(19) United States
(12) Patent Application Publication
(10) Pub. No.: US 2019/0141717 A1
(43) Pub. Date: May 9, 2019

(54) TECHNIQUES FOR INTERLEAVING IN SINGLE USER PREAMBLE PUNCTURING

(71) Applicant: QUALCOMM Incorporated, San Diego, CA (US)

(72) Inventors: Lin YANG, San Diego, CA (US); Bin TIAN, San Diego, CA (US); Jialing Li CHEN, San Diego, CA (US); Lochan VERMA, San Diego, CA (US); Sameer VERMANI, San Diego, CA (US); Ning ZHANG, Saratoga, CA (US); Kai SHI, San Jose, CA (US); Youhan KIM, Saratoga, CA (US); Vincent Knowles JONES, IV, Redwood City, CA (US)

(21) Appl. No.: 16/157,945

(22) Filed: Oct. 11, 2018

Related U.S. Application Data
(60) Provisional application No. 62/582,154, filed on Nov. 6, 2017.

(51) Int. Cl. H04W 72/08; H04L 5/00; H04L 1/00; H03M 13/11; H03M 13/00

(52) U.S. Cl. CPC H04W 72/082; H04L 5/0037; H04L 5/0051; H04L 1/0041; H04W 84/12; H04L 1/0071; H03M 13/1102; H03M 13/6527; H04L 1/0068

(57) ABSTRACT

Aspects of the present disclosure provide techniques for interleaving in single user (SU) preamble puncturing in wireless local area networks (WLANs). In one implementation, a wireless device can identify an SU preamble puncture transmission, encode information for the SU preamble puncture transmission to produce encoded bits, parse the encoded bits into multiple segments, parse the encoded bits among multiple resource units (RUs) within each of the multiple segments, and perform a tone interleaving of the encoded bits within each of the multiple RUs. These techniques can be used in a 6 GHz band, as well as a 2.4 GHz band or a 5 GHz band.

### CROSS-REFERENCE TO RELATED APPLICATION(S)

This application claims the benefit of U.S. Provisional Application Ser. No. 62/582,154, entitled “TECHNIQUES FOR INTERLEAVING IN SINGLE USER PREAMBLE PUNCTURING” and filed on Nov. 6, 2017, which is expressly incorporated by reference herein in its entirety.

### BACKGROUND

The deployment of wireless local area networks (WLANs) in the home, the office, and various public facilities is commonplace today. Such networks typically employ a wireless access point (AP) that connects a number of wireless stations (STAs) in a specific locality (e.g., home, office, public facility, etc.) to another network, such as the Internet or the like. A set of STAs can communicate with each other through a common AP in what is referred to as a basic service set (BSS).

With the increased use of WLANs, support for new bands (e.g., 6 GHz band) may be added to WLAN-based specifications such as IEEE 802.11ax, for example. Because of the presence of incumbent technologies in this band, it may be difficult to find contiguous 80 MHz or 160 MHz idle channels for operation. Preamble puncturing may be introduced to avoid interference with the incumbent technologies.

As such, it is desirable to provide techniques that allow for more flexibility in the implementation of preamble puncturing.

### SUMMARY

Aspects of the present disclosure address techniques for interleaving in single user (SU) preamble puncturing. The following description and the annexed drawings set forth in detail certain illustrative features of the one or more aspects. These features are indicative, however, of but a few of the various ways in which the principles of various aspects may be employed, and this description is intended to include all such aspects and their equivalents.

In an aspect, a method for wireless communications are described. The method may include identifying, by a wireless device, an SU preamble puncture transmission. The method may also include encoding information for the SU preamble puncture transmission to produce encoded bits. The method may further include parsing the encoded bits into multiple segments. The method may also include parsing the encoded bits among multiple resource units (RUs) within each of the multiple segments. The method may further include performing a tone interleaving of the encoded bits within each of the multiple RUs. These techniques can be used in a 6 GHz band, as well as a 2.4 GHz band or a 5 GHz band.

In an aspect, an apparatus for wireless communications is described. The apparatus may include a transceiver, a memory configured to store instructions, and a processor communicatively coupled with the memory. The processor may be configured to execute the instructions to identify a single user (SU) preamble puncture transmission. The processor may also be configured to execute the instructions to encode information for the SU preamble puncture transmission to produce encoded bits. The processor may further be configured to execute the instructions to parse the encoded bits into multiple segments. The processor may also be configured to execute the instructions to parse the encoded bits among multiple resource units (RUs) within each of the multiple segments. The processor may further be configured to execute the instructions to perform a tone interleaving of the encoded bits within each of the multiple RUs.

In another aspect, an apparatus for wireless communications is described. The apparatus may include means for identifying a single user (SU) preamble puncture transmission. The apparatus may also include means for encoding information for the SU preamble puncture transmission to produce encoded bits. The apparatus may further include means for parsing the encoded bits into multiple segments. The apparatus may also include means for parsing the encoded bits among multiple resource units (RUs) within each of the multiple segments. The apparatus may further include means for performing a tone interleaving of the encoded bits within each of the multiple RUs.

In another aspect, a computer-readable medium storing executable code for wireless communications is described. The computer-readable medium may store code for identifying a single user (SU) preamble puncture transmission. The computer-readable medium may also store code for encoding information for the SU preamble puncture transmission to produce encoded bits. The computer-readable medium may further store code for parsing the encoded bits into multiple segments. The computer-readable medium may also store code for parsing the encoded bits among multiple resource units (RUs) within each of the multiple segments. The computer-readable medium may further store code for performing a tone interleaving of the encoded bits within each of the multiple RUs.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIG. 1 is a conceptual diagram illustrating an example of a wireless local area network (WLAN) deployment;

FIG. 2 is a schematic diagram illustrating an example of a high-efficiency (HE) multi-user (MU) PLCP protocol data unit (PPDU) format;

FIG. 3 is a schematic diagram illustrating examples of currently supported preamble puncturing modes;

FIG. 4 is a table illustrating an example of signaling of preamble puncturing in IEEE 802.11ax;

FIG. 5A is a schematic diagram illustrating an example of tone planning to facilitate puncturing;

FIG. 5B is a schematic diagram illustrating another example of tone planning to facilitate puncturing;

FIG. 6 is a flow diagram illustrating an example of a method in accordance with aspects of the present disclosure;

FIG. 7 is a schematic diagram illustrating an example of various components in an access point (AP) in accordance with various aspects of the present disclosure; and

FIG. 8 is a schematic diagram illustrating an example of various components in a wireless station (STA) in accordance with various aspects of the present disclosure.

### DETAILED DESCRIPTION

The present disclosure describes techniques for interleaving in single user (SU) preamble puncturing. As described herein, these techniques may be implemented as methods, apparatuses, computer-readable media, and means for wireless communications.

As noted above, with the increased use of WLANs, support for new bands (e.g., 6 GHz band) may be added to WLAN-based specifications such as IEEE 802.11ax, for example. Because of the presence of incumbent technologies in this band, it may be difficult to find contiguous 80 MHz or 160 MHz idle channels for operation. Preamble puncturing may be introduced to avoid interference with the incumbent technologies.

IEEE 802.11ax introduces a preamble puncturing mode which allows non-primary 20 MHz channels to be zeroed out in >80 MHz bandwidth transmissions. This approach is currently only specified for downlink (DL) multi-user (MU) Physical Layer Convergence Procedure (PLCP) Protocol Data Unit (PPDU) and not for single user (SU) transmissions. Uplink (UL) preamble puncturing is generally possible using high-efficiency (HE) trigger-based (TB) PPDU. As it currently stands in the specification, each wireless station (STA) is allowed to be assigned to only one (1) resource unit (RU) (both UL and DL) so preamble puncturing may not be applied to SU transmission. This disclosure provides various techniques to expand preamble puncturing to SU transmissions in 6 GHz. These techniques, however, are also applicable to 2.4 GHz band or 5 GHz band.

This disclosure provides details on techniques for interleaving in SU preamble puncturing. To enable SU preamble puncturing related aspects may involve preamble signaling and PPDU format, tone planning and RU allocation, and encoding and interleaving.

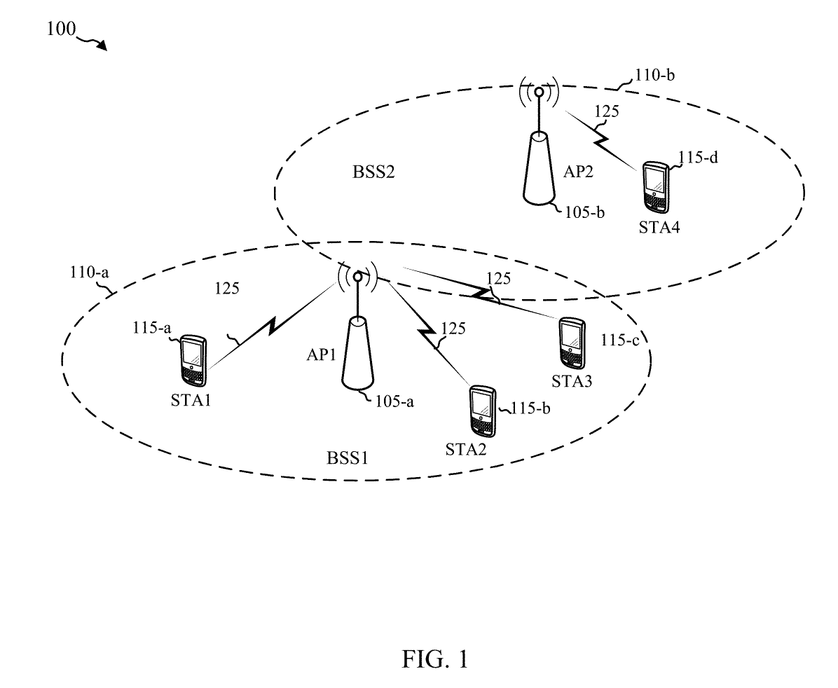

Various aspects are now described in more detail with reference to the FIGS. 1-8. In the following description, for purposes of explanation, numerous specific details are set forth in order to provide a thorough understanding of one or more aspects. It may be evident, however, that such aspect(s) may be practiced without these specific details. Additionally, the term “component” as used herein may be one of the parts that make up a system, may be hardware, firmware, and/or software stored on a computer-readable medium, and may be divided into other components.

The following description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in other examples.

FIG. 1 is a conceptual diagram 100 illustrating an example of a WLAN deployment in connection with various techniques described herein, including the various aspects described herein in connection with interleaving in SU preamble puncturing. The WLAN may include one or more access points (APs) 105 and one or more stations (STAs) 115 associated with a respective AP. One or more of the APs 105 and one or more of the STAs 115 may support the techniques described herein.

In the example of FIG. 1, there are two APs deployed: AP1 105-a in basic service set 1 (BSS1) and AP2 105-b in BSS2, which may be referred to as an overlapping BSS (OBSS). AP1 105-a is shown as having at least three associated STAs (STA1 115-a, STA2 115-b, STA3 115-c) and coverage area 110-a, while AP2 105-b is shown having one associated STA4 115-c and coverage area 110-b. The STAs and AP associated with a particular BSS may be referred to as members of that BSS. In the example of FIG. 1, the coverage area 110-a of AP1 105-a may overlap part of the coverage area of AP2 105-b such that a STA may be within the overlapping portion of the coverage areas 110-a and 110-b. The number of BSSs, APs, and STAs, and the coverage areas of the APs described in connection with the WLAN deployment of FIG. 1 are provided by way of illustration and not of limitation.

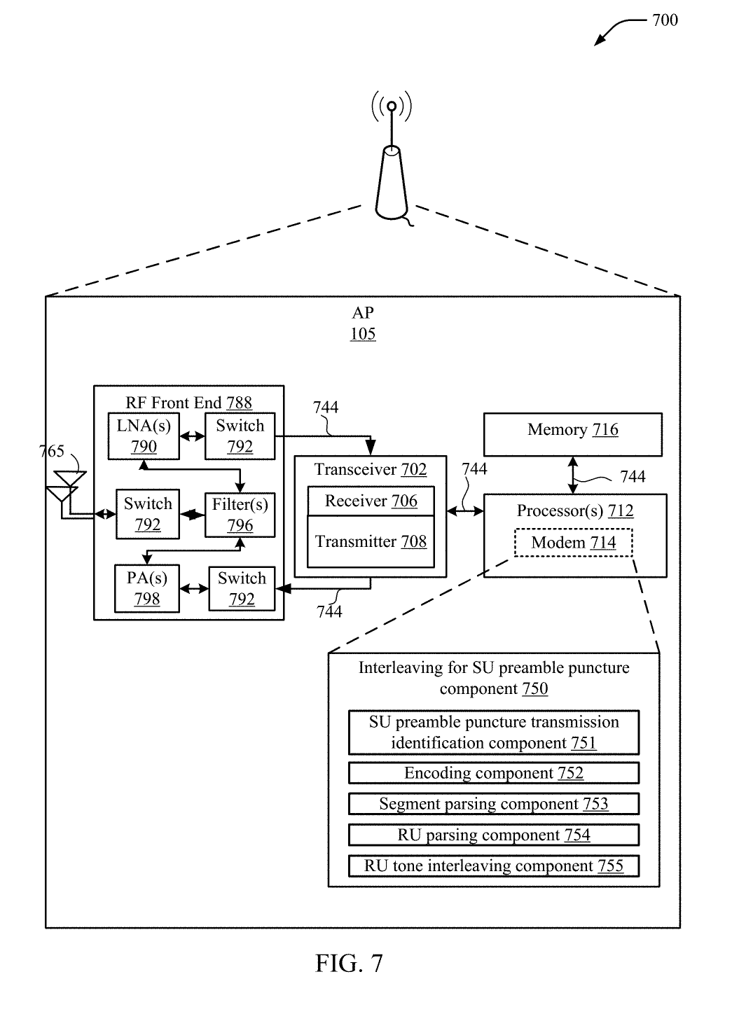

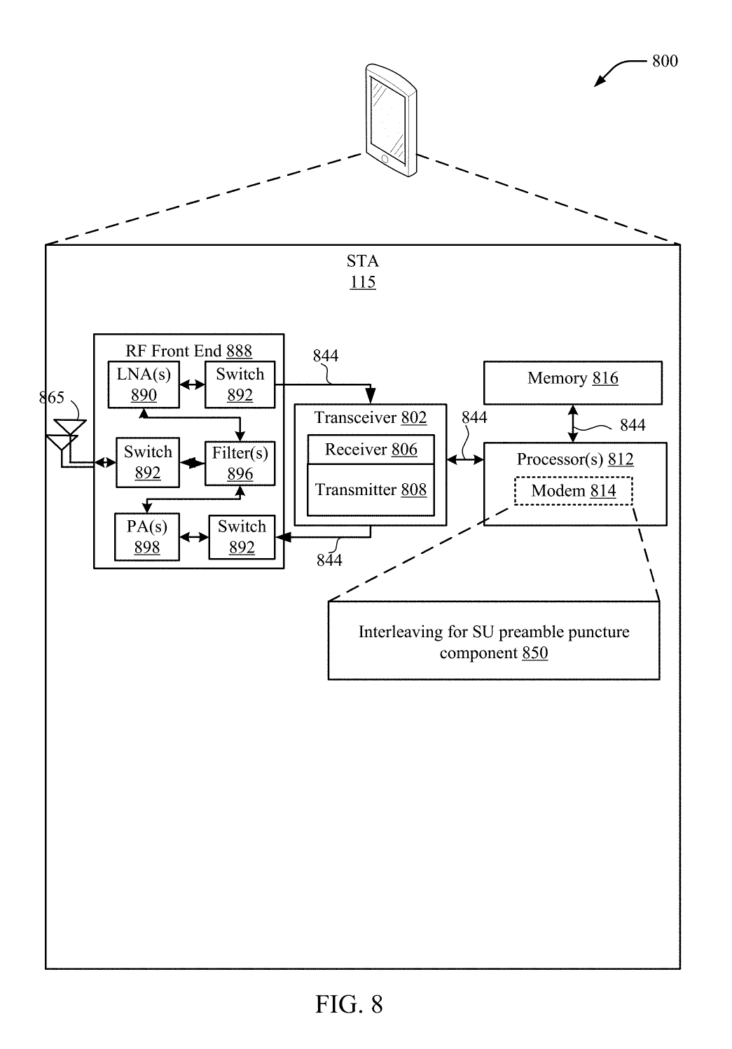

An STA 115 in FIG. 1, or in a similar WLAN deployment, can include a modem 814 (see FIG. 8) with an interleaving for SU preamble puncture component 850 as described in more detail below in FIG. 8 and that supports the interleaving preamble puncturing operations for SU transmissions described in this disclosure. Similarly, an AP 105 in FIG. 1, or in a similar deployment, can include a modem 714 (see FIG. 7) with an interleaving for SU preamble puncture component 750 as described in more detail below in FIG. 7 and that supports the interleaving preamble puncturing operations for SU transmissions described in this disclosure.

In some examples, the APs (e.g., AP1 105-a and AP2 105-b) shown in FIG. 1 are generally fixed terminals that provide backhaul services to STAs 115 within its coverage area or region. In some applications, however, the AP 105 may be a mobile or non-fixed terminal. The STAs (e.g., STA1 115-a, STA2 115-b, STA3 115-c, STA4 115-d) shown in FIG. 1, which may be fixed, non-fixed, or mobile terminals, utilize the backhaul services of their respective AP 105 to connect to a network, such as the Internet. Examples of an STA 115 include, but are not limited to: a cellular phone, a smart phone, a laptop computer, a desktop computer, a personal digital assistant (PDA), a personal communication system (PCS) device, a personal information manager (PIM), personal navigation device (PND), a global positioning system, a multimedia device, a video device, an audio device, a device for the Internet-of-Things (IoT), or any other suitable wireless apparatus requiring the backhaul services of an AP 105.

An STA 115 may also be referred to by those skilled in the art as: a subscriber station, a mobile unit, a subscriber unit, a wireless unit, a remote unit, a mobile device, a wireless device, a wireless communications device, a remote device, a mobile subscriber station, an access terminal, a mobile terminal, a wireless station, a remote terminal, a handset, a user agent, a mobile client, a client, user equipment (UE), or some other suitable terminology.

An AP 105 may also be referred to as: a base station, a base transceiver station, a radio base station, a radio transceiver, a transceiver function, or any other suitable terminology. The various concepts described throughout this disclosure are intended to apply to all suitable wireless apparatus regardless of their specific nomenclature. In an example, an STA that supports HE BSS operations may be referred to as an HE STA. Similarly, an AP that supports HE BSS operations may be referred to as an HE AP. Moreover, an HE STA may operate as an HE AP or as an HE mesh STA, for example.

Each of STA1 115-a, STA2 115-b, STA3 115-c, STA4 115-d may be implemented with a protocol stack. The protocol stack can include a physical layer for transmitting and receiving data in accordance with the physical and electrical specifications of the wireless channel, a data link layer for managing access to the wireless channel, a network layer for managing source to destination data transfer, a transport layer for managing transparent transfer of data between end users, and any other layers necessary or desirable for establishing or supporting a connection to a network.

Each of AP1 105-a and AP2 105-b can include software applications and/or circuitry to enable associated STAs 115 to connect to a network via communications link 125. The APs 105 can send frames or packets to their respective STAs 115 and receive frames or packets from their respective STAs 115 to communicate data and/or control information (e.g., signaling).

Each of AP1 105-a and AP2 105-b can establish communications link 125 with an STA 115 that is within the coverage area of the AP 105. Communications link 125 can comprise communications channels that can enable both UL and DL communications. When connecting to an AP 105, an STA 115 can first authenticate itself with the AP 105 and then associate itself with the AP 105. Once associated, communications link 125 may be established between the AP 105 and the STA 115 such that the AP 105 and the associated STA 115 may exchange frames or messages through a direct communications channel. It should be noted that the wireless communication system, in some examples, may not have a central AP (e.g., AP 105), but rather may function as a peer-to-peer network between the STAs 115. Accordingly, the functions of the AP 105 described herein may alternatively be performed by one or more of the STAs 115. Such systems may be referred to as an “ad-hoc” communication systems in which terminals asynchronously communication directly with each other without use of any specific AP referred to as an IBSS or mesh. Features of the present disclosure may be equally adaptable in such “ad-hoc” communication system where a broadcasting STA 115 function as the transmitting device of the plurality of multicast frames in lieu of the AP 105.

While aspects of the present disclosure are described in connection with a WLAN deployment or the use of IEEE 802.11-compliant networks, those skilled in the art will readily appreciate, the various aspects described throughout this disclosure may be extended to other networks employing various standards or protocols including, by way of example, BLUETOOTH® (Bluetooth), HiperLAN (a set of wireless standards, comparable to the IEEE 802.11 standards, used primarily in Europe), and other technologies used in wide area networks (WAN)s, WLANs, personal area networks (PAN)s, or other suitable networks now known or later developed. Thus, the various aspects presented throughout this disclosure for performing preamble puncturing operations may be applicable to any suitable wireless network regardless of the coverage range and the wireless access protocols utilized.

In some aspects, one or more APs (105-a and 105-b) may transmit on one or more channels (e.g., multiple narrowband channels, each channel including a frequency bandwidth) a beacon signal (or simply a “beacon”), via communications link 125 to STA(s) 115 of the wireless communication system, which may help the STA(s) 115 to synchronize their timing with the APs 105, or which may provide other information or functionality. Such beacons may be transmitted periodically. In one aspect, the period between successive beacon transmissions may be referred to as a beacon interval. Transmission of a beacon may be divided into a number of groups or intervals. In one aspect, the beacon may include, but is not limited to, such information as timestamp information to set a common clock, a peer-to-peer network identifier, a device identifier, capability information, a beacon interval, transmission direction information, reception direction information, a neighbor list, and/or an extended neighbor list, some of which are described in additional detail below. Thus, a beacon may include information that is both common (e.g., shared) amongst several devices and specific to a given device.

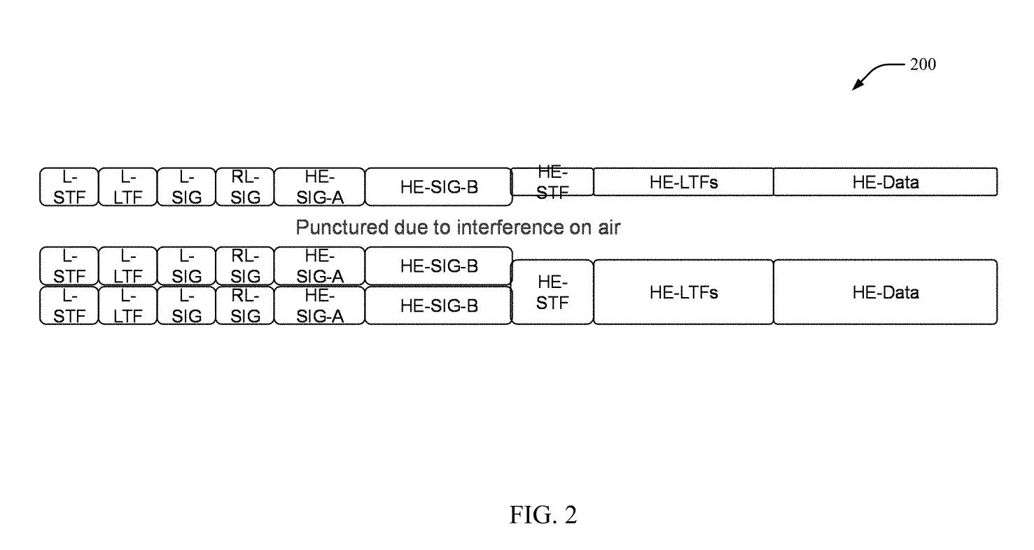

FIG. 2 shows a diagram 200 illustrating an example of an HE multi-user (MU) PPDU format as part of an overview of preamble puncturing supported by IEEE 802.11ax. Currently, preamble puncturing is only specified for DL and MU PPDU transmissions, and not for SU transmission. The pre-HE preamble (e.g., fields L-STF, L-LTF, L-SIG, RL-SIG, HE-SIG-A, and HE-SIG-B in the diagram 200) only transmits on the 20 MHz channels that are idle. The data portion is transmitted in orthogonal frequency-division multiple access (OFDMA) and avoids RU allocation in the 20 MHz channel with interference. As described above, UL preamble puncturing can be done using HE trigger-based PPDU. An AP (e.g., AP 105) may avoid the allocation of any clients in a busy 20 MHz channel. An STA (e.g., STA 115) may only transmit pre-HE preamble in the 20 MHz channels that overlap with its assigned RU. As mentioned above, each STA is allowed to be assigned to only one RU (both UL and DL) and therefore preamble puncturing is not supported for SU transmissions.

The present disclosure describes two approaches for SU preamble puncture signaling based on PPDU format.

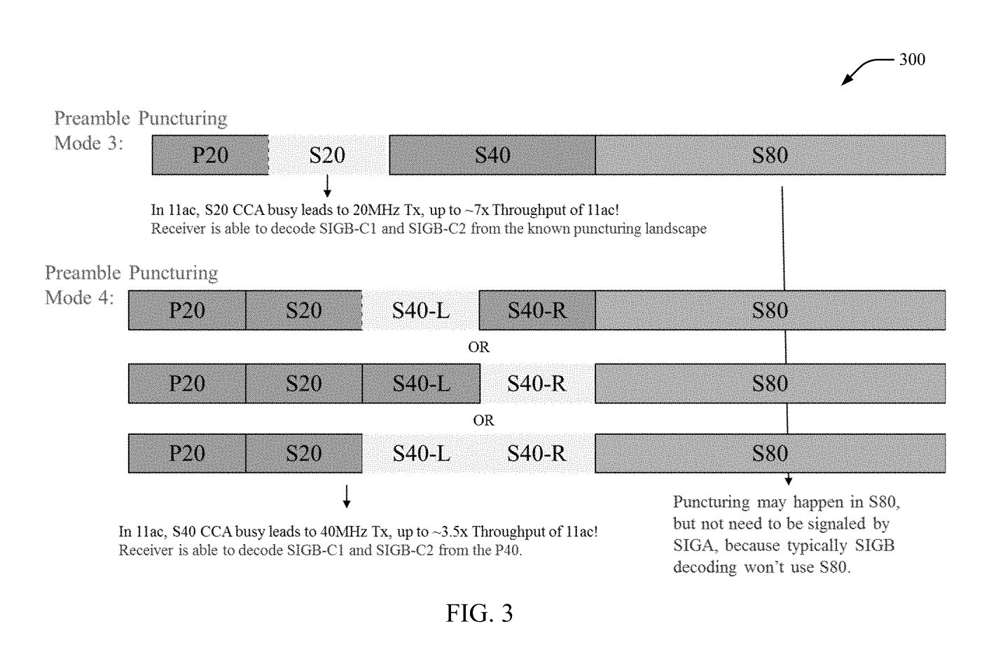

A first approach may be based on using an HE MU PPDU format such as the one shown in FIG. 2. In this approach, the existing HE-SIG-AIB signaling in MU preamble puncturing is reused. For example, HE-SIG-A field can indicate 4 preamble puncturing modes (some of which are described in more detail with respect to FIG. 3). Moreover, the HE-SIG-B field can indicate punctured RUs and assign all remaining RUs to the same STA.

UL can also use the HE MU PPDU for SU preamble puncture transmission. In this case, in the HE-SIG-B user specific field, an AP identifier (ID) is sent instead of an STA ID.

The approach that involves using HE MU PPDU format may have the benefits that it requires fewer modifications to the existing specification and may be backward compatible. On the other hand, this approach may require a higher preamble overhead than using SU PPDU as described below, and may only support a subset of all possible puncture modes due to the limitations in [1 2 1 2] structure of the HE-SIG-B field.

A second approach may be based on using an HE SU PPDU format. This approach may require changes to an SU tone plan of the data portion. Within this second approach, one option is to have a puncture pattern signaled through HE-SIGA preamble. One of the two reserved bits may be used to indicate a new HE-SIGA format for SU preamble puncturing. Moreover, 7 bits of HE-SIG-A (e.g., bitmap) may be repurposed to indicate per-20 MHz puncturing in 160 MHz. This option, however, may result in changes in the HE-SIG-A content from the current IEEE 802.11ax specification.

Within this second approach, another option is to signal a puncture pattern through management frame (e.g., a beacon, a management action frame, an association response frame). Certain channel/frequency range is indicated as exclusion zone (e.g., puncture region) in management frame to avoid interference with, for example, incumbent technologies. Transmissions in this BSS automatically zeros out RUs that overlap with the exclusion zone. This approach may not require a change to the HE-SIG-A preamble. In this option, both the receiver (e.g., STA 115) and the transmitter (e.g., AP 105) are aware of the puncturing due to the exclusion zone and the information provided by the management frame. Since the incumbent technologies tend not to change much, this option generally applies to semi static puncturing pattern. One limitation may be that it may not be possible to take advantage of idle channels varying from packet-to-packet.

FIG. 3 shows a diagram 300 illustrating examples of a third preamble puncturing mode for 160 MHz transmissions and a fourth preamble puncturing mode for 160 MHz transmissions. In the third preamble puncturing mode a secondary 20 MHz (S20) channel is punctured and in the fourth preamble puncturing mode a secondary 40 MHz left (S40-L) channel, a secondary 40 MHz right (S40-R) channel, or both are punctured. Other modes are also currently supported for HE MU PPDU, such as a first preamble puncturing mode for 80 MHz transmissions and a second preamble puncturing mode for 80 MHz transmissions, where in the first preamble puncturing mode a secondary 20 MHz (S20) channel is punctured and in the second preamble puncturing mode a secondary 40 MHz left (S40-L) channel or a secondary 40 MHz right (S40-R) channel is punctured.

The preamble puncturing modes shown in FIG. 3, and the other ones mentioned, are the only puncturing modes currently supported and provided but a limited number of all possible puncturing modes that can be used for preamble puncturing for SU transmissions.

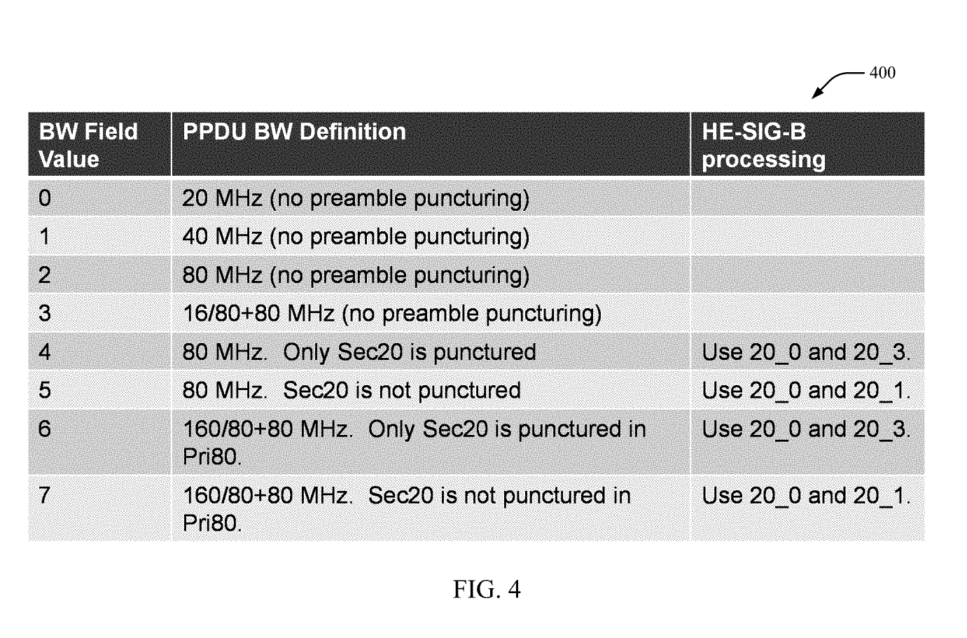

FIG. 4 shows a table 400 illustrating an example of signaling of preamble puncturing in IEEE 802.11ax. In this case, the table show a bandwidth (BW) field value, a PPDU Bandwidth definition, and an HE-SIG-B processing. In an aspect, 3 bits in HE-SIG-A may be used to indicate which HE-SIG-B content channel needs to be demodulated. For HE-SIG-B, it may be used to assign empty RUs in the 20 MHz channels with interference.

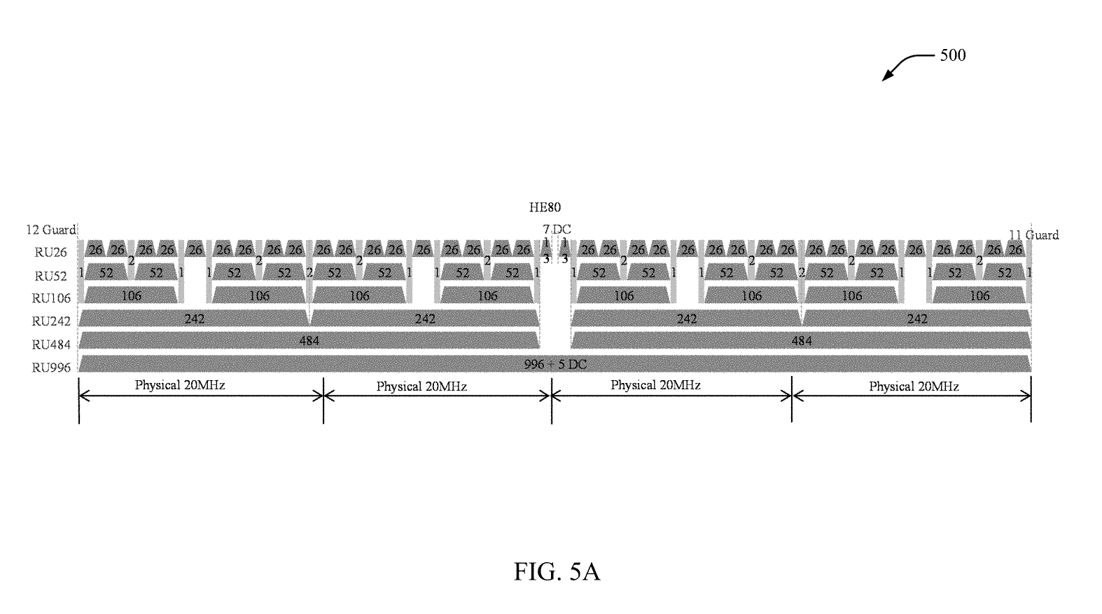

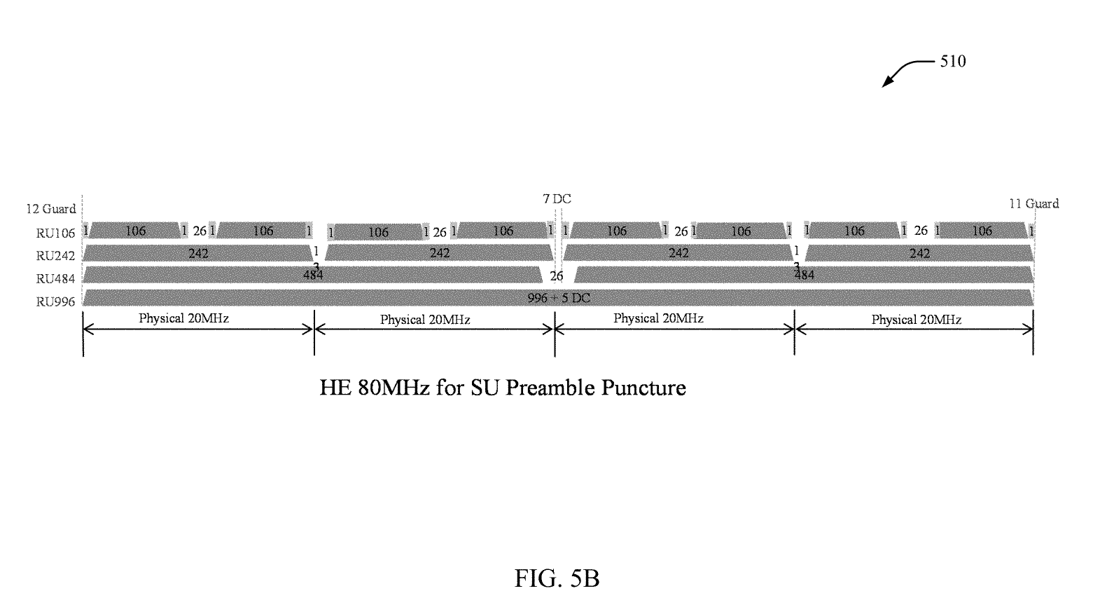

With respect to the tone planning and RU allocation described above, FIGS. 5A and 5B shows diagram 500 and 510 illustrating examples of tone planning to facilitate puncturing. To facilitate tone planning, SU preamble puncturing can use a tone plan similar to the one used for HE MU PPDU. Some possible improvements to the tone plan for SU preamble puncturing may include 20 MHz physical channel alignment by removing the center RU26 and shift the RU106 and RU242 in the 2nd and 3rd 20 MHz toward DC by 13 tones. Moreover, another aspect may include disallowing the usage of RU26 and RU52 for SU preamble puncturing transmission.

In order to enable SU preamble puncturing, the following aspects are considered. Multiple RUs can be allocated in one SU transmission. In some examples, a minimum RU size, such as 106 tones or 8 MHz (this may also be referred to as 10 MHz where 8 MHz and 106 tones is the effective channel width), may be used. All RUs may have the same modulation coding scheme (MCS), number of streams (Nsts), and transmission beamforming (TxBF) configuration. Joint encoding may be performed across all the RUs. Moreover, only low-density parity-check (LDPC) code may be used for SU preamble puncturing.

Interleaving in SU preamble puncturing involves a segment parsing operation, an RU parsing operation, and an LDPC tone interleaving within an RU operation. These operations may need to be performed after the puncturing. Interleaving in SU preamble puncturing needs to consider how to pack or arrange the coded bits into a few RUs and what kind of coding and interleaving to be used. Interleaving in SU preamble puncturing is typically associated with large bandwidths (e.g., 80 MHz, 160 MHz (contiguous or non-contiguous such as 80+80), or even 320 MHz (contiguous or non-contiguous)).

The segment parsing operation may be performed by a segment parser or segment parsing component (e.g., segment parsing component 753 or a per 80 MHz segment parser). The segment parser may evenly distribute coded bits among two segments, N_{BPSCS}/2 bits to segment 1 followed by N_{BPSCS}/2 to segment 2, and repeating until the segments are filled up with equal number of coded bits, where N_{BPSCS} indicates a number of coded bits per single carrier for each spatial stream. Because punctured segments have a smaller effective bandwidth (e.g., an 80 MHz transmission with a punctured 20 MHz channel has a 60 MHz effective channel width), one of the segments (segment 1 or segment 2) may be smaller than the other. In that case, the segment parser can be configured such that when a smaller segment fills up, all the remaining bits go to the larger segment. The bits in segment parsing may be associated with, for example, QAM symbols, such that the distribution may involve the distribution of in-phase bits and quadrature bits.

For the segment parsing operation, in the case of more than two segments (e.g., more than two 80 MHz segments), the segment parser may evenly distribute encoded bits among all the segments (N_{BPSCS}/(number of segments) bits for each segment). Once one of the segments gets filled up, the subsequent distribution of encoded bits will be done evenly among the remaining segments (e.g., those segments other than the one(s) already filled up) until only one segment is left unfilled. Then any remaining encoded bits will go to that last remaining segment that is unfilled.

The RU parsing operation is not something previously used because previously one RU was assigned or allocated for each STA. With multiple RUs, the RU parsing operation, which may be performed by an RU parser or RU parsing component (e.g., RU parsing component 754), involves distributing bits among RUs in each segment. One approach is to start from the lowest frequency RU, sequentially fill bits in each RU. Once all the bits in a symbol of one RU is filled up, move on to the next RU.

The LDPC tone interleaving within an RU operation, which may also be referred to as tone mapping or tone interleaving, may be perform by an RU tone interleaver or an RU tone interleaving component (e.g., RU tone interleaving component 755). The tones are now interleaved within each RU. The interleaving scheme that is used for interleaving within each of the multiple RUs may be the same as that supported in the current specification of the IEEE 802.11ax standard.

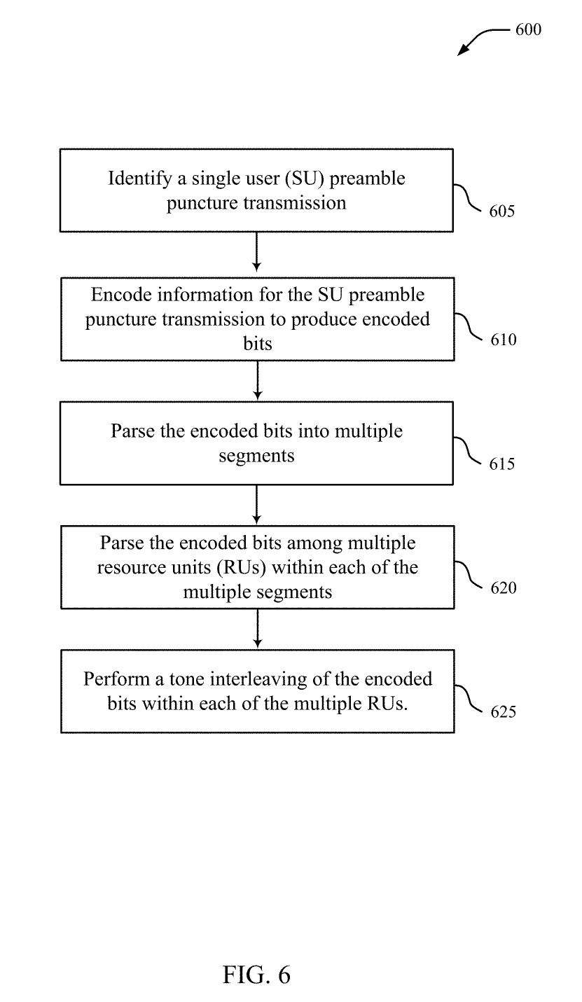

FIG. 6 is a flow diagram illustrating an example of a method 600 in accordance with aspects of the present disclosure. Aspects of the method 600 may be performed by one or more components of the AP 105 shown in FIG. 7, including but not limited to the processors 712, the modem 714, the transceiver 702, the memory 716, the radio frequency (RF) front end 788, and/or the interleaving for SU preamble puncture component 750. The interleaving for SU preamble puncture component 750 may include one or more subcomponents (see e.g., FIG. 7) that are configured to perform specific functions, actions, or processes associated with the method 600.

At 605, the method 600 includes identifying a single user (SU) preamble puncture transmission. In an example, one or more of the components of the AP 105 may identify an SU preamble puncture transmission based on BW signaling.

At 610, the method 600 includes encoding information for the SU preamble puncture transmission to produce encoded bits.

At 615, the method 600 includes parsing the encoded bits into multiple segments. In an aspect, one or more of the components and/or subcomponents (e.g., segment parsing component 753) of the AP 105 may parse the encoded bits into multiple segments. In an example, the encoded bits may be parsed into a number of coded bits per single carrier for each spatial stream divided by a desired number of segments (e.g., 2 or more segments).

At 620, the method 600 includes parsing the encoded bits among multiple resource units (RUs) within each of the multiple segments. In an aspect, one or more of the components and/or subcomponents (e.g., RU parsing component 754) of the AP 105 may parse the encoded bits among multiple resource units (RUs) within each of the multiple segments. For example, the AP 105 may distribute bits among RUs in each segment by starting from a lowest frequency RU, sequentially fill bits in each RU, and once all the bits in a symbol of one RU is filled up, moving on to a next RU.

At 625, the method 600 includes performing a tone interleaving of the encoded bits within each of the multiple RUs. In an aspect, one or more of the components and/or subcomponents (e.g., RU tone interleaving component 755) of the AP 105 may perform a tone interleaving of the encoded bits within each of the multiple RUs. For example, the AP 105 may perform LDPC tone interleaving.

In another aspect of the method 600, the parsing of the encoded bits into the multiple segments includes parsing the encoded bits into multiple 80 MHz segments.

In another aspect of the method 600, the multiple segments include two (2) 80 MHz segments or four (4) 80 MHz segments.

In another aspect of the method 600, the encoding of the information for the SU preamble puncture transmission includes performing a joint LDPC encoding of the information to produce the encoded bits.

In another aspect of the method 600, the multiple segments include a first segment and a second segment, and the parsing of the encoded bits into the multiple segments includes evenly distributing the encoded bits among the first segment and the second segment by repeatedly distributing N_{BPSCS}/2 encoded bits to the first segment and N_{BPSCS}/2 encoded bits to the second segment until the one segment with a smallest effective bandwidth fills up, any remaining encoded bits being assigned to the other segment, where N_{BPSCS} indicates number of coded bits per single carrier for each spatial stream.

In another aspect of the method 600, the parsing of the encoded bits among the multiple RUs within each of the multiple segments includes distributing the encoded bits in any one segment of the multiple segments by starting from a lowest frequency RU of the multiple RUs.

In another aspect of the method 600, once all of the encoded bits in a symbol of a particular RU are filled up, the method 600 may proceed to a next RU of the multiple RUs.

In another aspect of the method 600, the parsing of the encoded bits among the multiple RUs within each of the multiple segments includes sequentially filling bits in each RU of the multiple RUs.

In another aspect of the method 600, the performing of the tone interleaving of the encoded bits within each of the multiple RUs includes performing an LDPC tone mapping.

FIG. 7 describes hardware components and subcomponents of a wireless communications device (e.g., AP 105) for implementing the techniques for interleaving in SU preamble puncturing provided by this disclosure. For example, one example of an implementation of the AP 105 (e.g., a transmitter) may include a variety of components, including components such as one or more processors 712, the memory 716, the transceiver 702, and the modem 714 in communication via one or more buses 744, which may operate in conjunction with the interleaving for SU preamble puncture component 750 to enable one or more of the functions described herein as well as one or more methods (e.g., method 600) of the present disclosure. For example, the one or more processors 712, the memory 716, the transceiver 702, and/or the modem 714 may be communicatively coupled via the one or more buses 744. Further, the one or more processors 712, the modem 714, the memory 716, the transceiver 702, as well the RF front end 788, may be configured to support interleaving for SU preamble puncturing operations. In an example, the interleaving for SU preamble puncture component 750 may support the various approaches and/or options described above. For example, the interleaving for SU preamble puncture component 750 may support the use of HE MU PPDU format or HE SU PPDU format.

In an aspect, the one or more processors 716 may include the modem 714 that may use one or more modem processors. The various functions related to the interleaving for SU preamble puncture component 750 may be included in the modem 714 and/or the one or more processors 712 and, in an aspect, can be executed by a single processor, while in other aspects, different ones of the functions may be executed by a combination of two or more different processors. For example, in an aspect, the one or more processors 712 may include any one or any combination of a modem processor, or a baseband processor, or a digital signal processor, or a transmit processor, or a receiver processor, or a transceiver processor associated with the transceiver 702. In other aspects, some of the features of the one or more processors 712 and/or the modem 714 associated with the interleaving for SU preamble puncture component 750 may be performed by the transceiver 702.

Also, the memory 716 may be configured to store data used herein and/or local versions of applications or the interleaving for SU preamble puncture component 750 and/or one or more of its subcomponents being executed by at least one processor 712. The memory 716 can include any type of computer-readable medium usable by a computer or at least one processor 712, such as random access memory (RAM), read only memory (ROM), tapes, magnetic discs, optical discs, volatile memory, non-volatile memory, and any combination thereof. In an aspect, for example, the memory 716 may be a non-transitory computer-readable storage medium that stores one or more computer-executable codes defining the interleaving for SU preamble puncture component 750 and/or one or more of its subcomponents, and/or data associated therewith, when the AP 105 is operating at least one processor 712 to execute the interleaving for SU preamble puncture component 750 and/or one or more of its subcomponents.

The transceiver 702 may include at least one receiver 706 and at least one transmitter 708. The receiver 706 may include hardware, firmware, and/or software code executable by a processor for receiving data, the code comprising instructions and being stored in a memory (e.g., computer-readable medium). The receiver 706 may be, for example, a radio frequency (RF) receiver. In an aspect, the receiver 706 may receive signals transmitted by at least one wireless communications device (e.g., STA 115). Additionally, the receiver 706 may process such received signals, and also may obtain measurements of the signals, such as, but not limited to, energy per chip to interference power ratio (Ec/Io), signal-to-noise ratio (SNR), reference signal received power (RSRP), received signal strength indicator (RSSI), etc. The transmitter 708 may include hardware, firmware, and/or software code executable by a processor for transmitting data, the code comprising instructions and being stored in a memory (e.g., computer-readable medium). A suitable example of the transmitter 708 may include, but is not limited to, an RF transmitter.

Moreover, in an aspect, the wireless communications device or AP 105 may include the RF front end 788 mentioned above, which may operate in communication with the one or more antennas 765 and the transceiver 702 for receiving and transmitting radio transmissions. The RF front end 788 may be connected to the one or more antennas 765 and can include one or more low-noise amplifiers (LNAs) 790, one or more switches 792, one or more power amplifiers (PAs) 798, and one or more filters 796 for transmitting and receiving RF signals.

In an aspect, the LNA 790 can amplify a received signal at a desired output level. In an aspect, each LNA 790 may have a specified minimum and maximum gain values. In an aspect, the RF front end 788 may use the one or more switches 792 to select a particular LNA 790 and its specified gain value based on a desired gain value for a particular application.

Further, for example, the one or more PA(s) 798 may be used by the RF front end 788 to amplify a signal for an RF output at a desired output power level. In an aspect, each PA 798 may have specified minimum and maximum gain values. In an aspect, the RF front end 788 may use the one or more switches 792 to select a particular PA 798 and its specified gain value based on a desired gain value for a particular application.

Also, for example, the one or more filters 796 may be used by the RF front end 788 to filter a received signal to obtain an input RF signal. Similarly, in an aspect, for example, a respective filter 496 can be used to filter an output from a respective PA 798 to produce an output signal for transmission. In an aspect, each filter 796 can be connected to a specific LNA 790 and/or PA 798. In an aspect, the RF front end 788 can use one or more switches 792 to select a transmit or receive path using a specified filter 796, LNA 790, and/or PA 798, based on a configuration as specified by the transceiver 702 and/or the one or more processors 712.

As such, the transceiver 702 may be configured to transmit and receive wireless signals through the one or more antennas 765 via the RF front end 788. In an aspect, the transceiver 702 may be tuned to operate at specified frequencies. In an aspect, for example, the modem 714 can configure the transceiver 702 to operate at a specified frequency and power level based on the configuration of the wireless communications device or AP 105 and the communication protocol used by the modem 714.

In an aspect, the modem 714 can be a multiband-multimode modem, which can process digital data and communicate with the transceiver 702 such that the digital data is sent and received using the transceiver 702. In an aspect, the modem 714 can be multiband and be configured to support multiple frequency bands for a specific communications protocol. In an aspect, the modem 714 can be multimode and be configured to support multiple operating networks and communications protocols. In an aspect, the modem 714 can control one or more components of wireless communications device or AP 105 (e.g., the RF front end 788, the transceiver 702) to enable transmission and/or reception of signals based on a specified modem configuration. In an aspect, the modem configuration may be based on the mode of the modem and the frequency band in use. In another aspect, the modem configuration may be based on AP configuration information associated with wireless communications device or AP 105.

The interleaving for SU preamble puncture component 750 may include an SU preamble puncture transmission identification component 751 configured to identify based on information to be transmitted and/or puncturing regions or exclusion zones when a single user (SU) preamble puncture transmission is to take place.

The interleaving for SU preamble puncture component 750 may include an encoding component 752 configured to encode information for the SU preamble puncture transmission to produce encoded bits. The encoding may be based on a joint encoding as described above.

The interleaving for SU preamble puncture component 750 may include a segment parsing component 753 configured to parse the encoded bits into multiple segments. The segment parsing component 753 may be based on an 80 MHz segment parser that may be able to handle multiple 80 MHz segments.

The interleaving for SU preamble puncture component 750 may include an RU parsing component 754 configured to parse the encoded bits among multiple resource units (RUs) within each of the multiple segments.

The interleaving for SU preamble puncture component 750 may include an RU tone interleaving component 755 configured to perform a tone interleaving of the encoded bits within each of the multiple RUs.

For example, FIG. 8 describes hardware components and subcomponents of an STA 115 (e.g., receiver) for implementing the techniques for interleaving in SU preamble puncturing provided by this disclosure. The STA 115 may include one or more processors 812, a memory 816, a modem 814, and a transceiver 802, which may communicate between them using a bus 844. For example, the one or more processors 812, the memory 816, the transceiver 802, and/or the modem 814 may be communicatively coupled via the one or more buses 844. The transceiver 802 may include a receiver 806 and a transmitter 808. Moreover, the STA 115 may include an RF front end 888 and one or more antennas 865, where the RF front end 888 may include LNA(s) 890, switches 892, filters 896, and PA(s) 898. Each of these components or subcomponents of the STA 115 may operate in a similar manner as the corresponding components described above in connection with FIG. 7.

The one or more processors 812, the memory 816, the transceiver 802, and the modem 814 may operate in conjunction with the interleaving for SU preamble puncture component 850 to enable one or more of the functions described herein in connection with an STA (e.g., receiver) for interleaving in SU preamble puncturing. In one aspect, the interleaving for SU preamble puncture component 850 may be configured to perform one or more complimentary functions to those performed by the interleaving for SU preamble puncture component 750 in FIG. 7.

The above detailed description set forth above in connection with the appended drawings describes examples and does not represent the only examples that may be implemented or that are within the scope of the claims. The term “example,” when used in this description, means “serving as an example, instance, or illustration,” and not “preferred” or “advantageous over other examples.” The detailed description includes specific details for the purpose of providing an understanding of the described techniques. These techniques, however, may be practiced without these specific details. In some instances, well-known structures and apparatuses are shown in block diagram form in order to avoid obscuring the concepts of the described examples.

Information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, computer-executable code or instructions stored on a computer-readable medium, or any combination thereof.

The various illustrative blocks and components described in connection with the disclosure herein may be implemented or performed with a specially-programmed device, such as but not limited to a processor, a digital signal processor (DSP), an ASIC, a FPGA or other programmable logic device, a discrete gate or transistor logic, a discrete hardware component, or any combination thereof designed to perform the functions described herein. A specially-programmed processor may be a microprocessor, but in the alternative, the processor may be any conventional processor, controller, microcontroller, or state machine. A specially-programmed processor may also be implemented as a combination of computing devices, e.g., a combination of a DSP and a microprocessor, multiple microprocessors, one or more microprocessors in conjunction with a DSP core, or any other such configuration.

The functions described herein may be implemented in hardware, software executed by a processor, firmware, or any combination thereof. If implemented in software executed by a processor, the functions may be stored on or transmitted over as one or more instructions or code on a non-transitory computer-readable medium. Other examples and implementations are within the scope and spirit of the disclosure and appended claims. For example, due to the nature of software, functions described above can be implemented using software executed by a specially programmed processor, hardware, firmware, hardwiring, or combinations of any of these. Features implementing functions may also be physically located at various positions, including being distributed such that portions of functions are implemented at different physical locations. Also, as used herein, including in the claims, “or” as used in a list of items prefaced by “at least one of” indicates a disjunctive list such that, for example, a list of “at least one of A, B, or C” means A or B or C or AB or AC or BC or ABC (i.e., A and B and C).

Computer-readable media includes both computer storage media and communication media including any medium that facilitates transfer of a computer program from one place to another. A storage medium may be any available medium that can be accessed by a general purpose or special purpose computer. By way of example, and not limitation, computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The previous description of the disclosure is provided to enable a person skilled in the art to make or use the disclosure. Various modifications to the disclosure will be readily apparent to those skilled in the art, and the common principles defined herein may be applied to other variations without departing from the spirit or scope of the disclosure. Furthermore, although elements of the described aspects and/or embodiments may be described or claimed in the singular, the plural is contemplated unless limitation to the singular is explicitly stated. Additionally, all or a portion of any aspect and/or embodiment may be utilized with all or a portion of any other aspect and/or embodiment, unless stated otherwise. Thus, the disclosure is not to be limited to the examples and designs described herein but is to be accorded the widest scope consistent with the principles and novel features disclosed herein.

Moreover, nothing disclosed herein is intended to be dedicated to the public regardless of whether such disclosure is explicitly recited in the claims. No claim element is to be construed under the provisions of 35 U.S.C. § 112 (f), unless the element is expressly recited using the phrase “means for” or, in the case of a method claim, the element is recited using the phrase “step for.”

What is claimed is:

1. A method of wireless communications by a wireless device, comprising:
identifying a single user (SU) preamble puncture transmission;
encoding information for the SU preamble puncture transmission to produce encoded bits;
parsing the encoded bits into multiple segments;
parsing the encoded bits among multiple resource units (RUs) within each of the multiple segments; and
performing a tone interleaving of the encoded bits within each of the multiple RUs.

2. The method of claim 1, wherein the parsing of the encoded bits into the multiple segments includes parsing the encoded bits into multiple 80 MHz segments.

3. The method of claim 1, wherein the multiple segments include two (2) 80 MHz segments or four (4) 80 MHz segments.

4. The method of claim 1, wherein the encoding of the information for the SU preamble puncture transmission includes performing a joint low-density parity-check (LDPC) encoding of the information to produce the encoded bits.

5. The method of claim 1, wherein:
the multiple segments include a first segment and a second segment, and
the parsing of the encoded bits into the multiple segments includes evenly distributing the encoded bits among the first segment and the second segment by repeatedly distributing N_{BPSCS}/2 encoded bits to the first segment and N_{BPSCS}/2 encoded bits to the second segment until the one segment with a smallest effective bandwidth fills up, any remaining encoded bits being assigned to the other segment, where N_{BPSCS} indicates a number of coded bits per single carrier for each spatial stream.

6. The method of claim 1, wherein:
the multiple segments include more than two segments, and
the parsing of the encoded bits into the multiple segments includes evenly distributing encoded bits among all the multiple segments, where N_{BPSCS}/2 bits are provided for each segment, until one of the multiple segments gets filled up, the subsequent distribution of encoded bits being done evenly among the remaining segments of the multiple segments that have not been filled up until only one segment is left unfilled and then any remaining encoded bits go to that last remaining segment that is unfilled, where N_{BPSCS} indicates a number of coded bits per single carrier for each spatial stream.

7. The method of claim 1, wherein the parsing of the encoded bits among the multiple RUs within each of the multiple segments includes distributing the encoded bits in any one segment of the multiple segments by starting from a lowest frequency RU of the multiple RUs.

8. The method of claim 7, wherein once all of the encoded bits in a symbol of a particular RU are filled up, proceeding to a next RU of the multiple RUs.

9. The method of claim 7, wherein parsing of the encoded bits among the multiple RUs within each of the multiple segments includes sequentially filling bits in each RU of the multiple RUs.

10. The method of claim 1, wherein the performing of the tone interleaving of the encoded bits within each of the multiple RUs includes performing a low-density parity-check (LDPC) tone mapping.

11. The method of claim 1, wherein the multiple RUs are allocated in one SU transmission.

12. The method of claim 11, wherein a minimum RU size of the multiple RUs is configurable.

13. The method of claim 12, wherein the minimum RU size is 106 tones or 8 MHz.

14. The method of claim 1, wherein each of the multiple RUs have the same modulation coding scheme (MCS), number of streams (Nsts), and transmission beamforming (TxBF) configuration.

15. The method of claim 1, wherein the encoding of the information for the SU preamble puncture transmission includes performing a joint encoding across all of the RUs.

16. The method of claim 15, wherein only a low-density parity-check (LDPC) code is used for SU preamble puncture transmission.

17. An apparatus for wireless communications, comprising:
a transceiver;
a memory configured to store instructions; and
a processor communicatively coupled with the memory, the processor configured to execute the instructions to:
identify a single user (SU) preamble puncture transmission;
encode information for the SU preamble puncture transmission to produce encoded bits;
parse the encoded bits into multiple segments;
parse the encoded bits among multiple resource units (RUs) within each of the multiple segments; and
perform a tone interleaving of the encoded bits within each of the multiple RUs.

18. The apparatus of claim 17, wherein the processor is further configured to execute the instructions to:
parse the encoded bits into multiple 80 MHz segments.

19. The apparatus of claim 17, wherein the multiple segments include two (2) 80 MHz segments or four (4) 80 MHz segments.

20. The apparatus of claim 17, wherein the processor is further configured to execute the instructions to:
perform a joint low-density parity-check (LDPC) encoding of the information to produce the encoded bits.

21. The apparatus of claim 17, wherein:
the multiple segments include a first segment and a second segment, and
the processor is further configured to execute the instructions to:
evenly distribute the encoded bits among the first segment and the second segment by repeatedly distributing N_{BPSCS}/2 encoded bits to the first segment and N_{BPSCS}/2 encoded bits to the second segment until the one segment with a smallest effective bandwidth fills up, any remaining encoded bits being assigned to the other segment, where N_{BPSCS} indicates a number of coded bits per single carrier for each spatial stream.

22. The apparatus of claim 17, wherein:
the multiple segments include more than two segments, and
the processor is further configured to execute the instructions to:
evenly distribute encoded bits among all the multiple segments, where N_{BPSCS}/2 bits are provided for each segment, until one of the multiple segments gets filled up, the subsequent distribution of encoded bits being done evenly among the remaining segments of the multiple segments that have not been filled up until only one segment is left unfilled and then any remaining encoded bits go to that last remaining segment that is unfilled, where N_{BPSCS} indicates a number of coded bits per single carrier for each spatial stream.

23. The apparatus of claim 17, wherein the processor is further configured to execute the instructions to:
distribute the encoded bits in any one segment of the multiple segments by starting from a lowest frequency RU of the multiple RUs.

24. The apparatus of claim 23, wherein the processor is further configured to execute the instructions to:
proceed to a next RU of the multiple RUs, once all of the encoded bits in a symbol of a particular RU are filled up.

25. The apparatus of claim 23, wherein the processor is further configured to execute the instructions to:
sequentially fill bits in each RU of the multiple RUs.

26. The apparatus of claim 17, wherein the processor is further configured to execute the instructions to:
perform a low-density parity-check (LDPC) tone mapping.

27. The apparatus of claim 17, wherein the multiple RUs are allocated in one SU transmission.

28. The apparatus of claim 27, wherein a minimum RU size of the multiple RUs is configurable.

29. The apparatus of claim 28, wherein the minimum RU size is 106 tones or 8 MHz.

30. The apparatus of claim 17, wherein each of the multiple RUs have the same modulation coding scheme (MCS), number of streams (Nsts), and transmission beamforming (TxBF) configuration.

31. The apparatus of claim 17, wherein the processor is further configured to execute the instructions to:
perform a joint encoding across all of the RUs.

32. The apparatus of claim 31, wherein only a low-density parity-check (LDPC) code is used for SU preamble puncture transmission.

33. An apparatus for wireless communications, comprising:
means for identifying a single user (SU) preamble puncture transmission;
means for encoding information for the SU preamble puncture transmission to produce encoded bits;
means for parsing the encoded bits into multiple segments;
means for parsing the encoded bits among multiple resource units (RUs) within each of the multiple segments; and
means for performing a tone interleaving of the encoded bits within each of the multiple RUs.

34. A computer-readable medium storing executable code for wireless communications, the computer-readable medium comprising:
code for identifying a single user (SU) preamble puncture transmission;
code for encoding information for the SU preamble puncture transmission to produce encoded bits;
code for parsing the encoded bits into multiple segments;
code for parsing the encoded bits among multiple resource units (RUs) within each of the multiple segments; and
code for performing a tone interleaving of the encoded bits within each of the multiple RUs.
